(19) United States
(12) Patent Application Publication
(10) Pub. No.: US 2010/0110751 A1
(43) Pub. Date: May 6, 2010

(54) SEMICONDUCTOR STORAGE DEVICE

(75) Inventors: Kentaro Miyajima, Uenohara (JP); Takeo Yamashita, Ome (JP); Tomoo Murata, Fussa (JP)

Correspondence Address: MILES & STOCKBRIDGE PC, 1751 PINNACLE DRIVE, SUITE 500, MCLEAN, VA, 22102-3833, US

(73) Assignee: HITACHI, LTD.

(21) Appl. No.: 12/603,623

(22) Filed: Oct. 22, 2009

(30) Foreign Application Priority Data
Oct. 24, 2008 (JP) JP2008-273726

(51) Int. Cl. G11C 11/00; G11C 7/00; G11C 8/08; G11C 17/18

(52) U.S. Cl. 365/100; 365/189.2; 365/230.06; 365/225.7; 365/148

(57) ABSTRACT

In a configuration having a nonvolatile memory and a volatile memory, when storage information of the nonvolatile memory is changed and an abnormal operation occurs due to temporary blackout, α-ray or others, the abnormal operation is recovered to a normal operation regardless of the presence of the detection of the abnormal operation. A reset to be inputted to the nonvolatile memory is collectively transmitted for each 1 bit, each 1 word or each predetermined arbitrary bit, and the collectively transmitted reset serving as one unit is periodically transmitted, so that the abnormal operation is recovered to a normal operation without input signals from outside even if the storage information of the nonvolatile memory is changed due to temporary blackout, α-ray or others.

### CROSS-REFERENCE TO RELATED APPLICATION

The present application claims priority from Japanese Patent Application No. JP 2008-273726 filed on Oct. 24, 2008, the content of which is hereby incorporated by reference into this application.

### FIELD OF THE INVENTION

The present invention relates to a semiconductor storage device. More particularly, the present invention relates to a semiconductor storage device configured with a nonvolatile memory and a volatile memory.

### BACKGROUND OF THE INVENTION

Conventionally, a resistive random-access memory (resistance change memory) has been used as one of nonvolatile memories (for example, see Japanese Patent Application Laid-Open Publication No. 2006-146983 (Patent Document 1)).

### SUMMARY OF THE INVENTION

Prior to the present invention, the inventors of the present invention and others have studied on the reduction in power consumption of a nonvolatile memory with using a volatile memory. FIGS. 4 and 5 of the above-described Patent Document 1 illustrate the transfer of storage content in the nonvolatile memory to the volatile memory upon power-ON.

However, the present inventors and others have found out that, when this circuit configuration is used in a system in which the power supply has to be always turned ON for a long time or a system in which the low power consumption is required like the battery driving, the storage content in a nonvolatile memory is changed due to temporary blackout of power supply voltage, voltage drop or α-ray to cause an abnormal operation, and the abnormal operation cannot be recovered to a normal operation without inputting signals from outside.

A preferred aim of the present invention is to solve the above-described issues and achieve performance improvement of a semiconductor storage device.

A typical example of the present invention will be described as follows. That is, a semiconductor storage device according to the present invention includes: a nonvolatile memory; a volatile memory whose input is connected to an output of the nonvolatile memory; and a reset signal generating unit connected to an input of the nonvolatile memory, and has a function of periodically transferring data from the nonvolatile memory to the volatile memory in accordance with a logical value of an output signal from the reset signal generating unit.

According to the present invention, the reliability of a multi-bit (for example, exceeding 1 kilobit) PROM against temporary blackout can be secured with low power consumption.

### BRIEF DESCRIPTIONS OF THE DRAWINGS

FIG. 1 is a diagram illustrating connecting relations among components each configuring an embodiment of a semiconductor storage device according to the present invention including a resistance-division-type PROM, an SRAM and a reset signal generating logic circuit;

FIG. 2A is a diagram illustrating a whole configuration of the resistance-division-type PROM configuring the semiconductor storage device of FIG. 1;

FIG. 2B is a diagram illustrating relations among an input signal of the resistance-division-type PROM of FIG. 2A, an output signal of the same and current of the same;

FIG. 2C is a diagram illustrating a whole configuration of the resistance-division-type PROM when an antifuse element is used as a variable resistor in FIG. 2A;

FIG. 2D is a diagram illustrating a whole configuration of the resistance-division-type PROM when a fuse element is used as the variable resistor in FIG. 2A;

FIG. 3 is a diagram illustrating an operation of the semiconductor storage device when “0” is written in another embodiment of using an antifuse element of a bipolar transistor as a variable resistor of the resistance-division-type PROM configuring the semiconductor storage device of FIG. 1;

FIG. 4 is a diagram illustrating an operation of the semiconductor storage device when storage information of the resistance-division-type PROM written by the operation of FIG. 3 is written to the SRAM;

FIG. 5 is a diagram illustrating an operation of the semiconductor storage device when the storage information of the SRAM written by the operation of FIG. 4 is outputted;

FIG. 6A is a diagram illustrating still another embodiment of a circuit configuration of the reset signal generating logic circuit configuring the semiconductor storage device of FIG. 1;

FIG. 6B is a diagram illustrating a timing chart of each signal waveform in the reset signal generating logic circuit of FIG. 6A;

FIG. 7 is a diagram illustrating a configuration of a memory array of n×m bits in which the semiconductor storage device of FIG. 1 is applied as a memory cell and reset signals are commonly connected for each word line;

FIG. 8 is a diagram illustrating a configuration of a memory array of n×m bits in which the semiconductor storage device of FIG. 1 is applied as the memory cell and the reset signal is connected to the reset signal generating logic circuit for each 1 bit; and

FIG. 9 is a diagram illustrating a timing chart expressing timing relations among signals when a 4-bit memory abnormally operated due to rapid drop of power supply voltage is recovered to a normal operation.

### DETAILED DESCRIPTIONS OF THE PREFERRED EMBODIMENTS

Hereinafter, embodiments of the present invention will be described in detail with reference to figures.

### First Embodiment

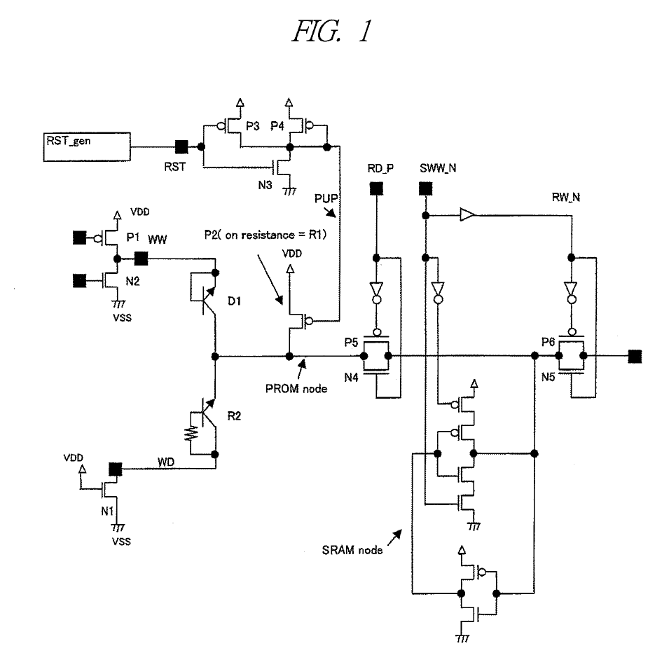

FIG. 1 illustrates an embodiment of a whole circuit configuration of a semiconductor storage device according to the present invention including a resistance-division-type PROM, an SRAM and a reset signal generating logic circuit (RST_gen). As a reset signal, continuous pulses generated by a pulse generator inside IC or an external pulse generator are collectively transmitted to a nonvolatile memory for each 1 bit, each 1 word or each predetermined arbitrary bit, and the collectively transmitted pulses serving as one unit are periodically transmitted.

In FIG. 1, a symbol R2 denotes an antifuse resistor element in which a junction between an emitter and a base of a bipolar transistor is broken to short out between the emitter and a collector, thereby decreasing a resistance value. A symbol D1 connected to R2 in series denotes a diode-connected bipolar transistor, and it carries current in a forward direction upon shorting out between the emitter and the collector of R2. A PMOS transistor denoted by a symbol P1 and an NMOS transistor denoted by a symbol N2 are connected to D1 in series, and an NMOS transistor denoted by a symbol N1 is connected to R2 in series. Upon shorting out between the emitter and the collector of R2, a gate voltage of N1 is set to VDD and a gate voltage of P1 is set to VSS to carry current from a power supply terminal VDD of P1 to a power supply terminal VSS of N1 via D1 and R2. Gate terminals of a PMOS transistor denoted by a symbol P3 and an NMOS transistor denoted by a symbol N3 are connected to an output of the reset generating logic circuit (RST_gen), and a gate terminal and a drain terminal of a PMOS transistor denoted by a symbol P4 are connected to both of N3 and P3. N3 and P4 receive pulse signals generated from the reset generating logic circuit (RST_gen) to be turned ON, so that voltage of a node PUP connected to a gate terminal of a PMOS transistor denoted by a symbol P2 is dropped. Accordingly, the PMOS P2 is turned ON. When a value of ON resistance at this time is assumed to R1, voltage of a PROM storage node (PROM node) becomes a value of “VDD-R1×VDD/(R1+R2)”, so that information of 1 or 0 is outputted. A PMOS transistor denoted by a symbol P5 and an NMOS transistor denoted by a symbol N4 are connected to the PROM storage node, and gate terminals of P5 and N4 are controlled by RD_P. The RD_P synchronizes with a pulse signal generated from the reset generating logic circuit (RST_gen) to increase its voltage from VSS to VDD, so that P5 and N4 are turned ON to input a logical value of the PROM storage node into an SRAM. At the same time, voltage of SWW_N is dropped from VDD to VSS to write the inputted logical value of the PROM storage node into the SRAM. By setting a voltage of the RD_P from VDD to VSS and a voltage of the SWW_N from VSS to VDD at the time of dropping the voltage of the output of the reset generating logic circuit (RST_gen) to VSS, the logical value written in the SRAM is outputted to outside via a PMOS transistor denoted by a symbol P6 and an NMOS transistor denoted by a symbol N5 which are connected to each other in series.

In the resistance-division-type PROM, current “I” flows from a VDD terminal of the P2 toward a VSS terminal of the N1 to determine the logical value from a resistance ratio between the R1 and the R2. At this time, when a resistance value of R2 is decreased by shorting out between the emitter and the base of R2 to output a logical value “0”, the current I increases. Therefore, according to the configuration of the present embodiment of FIG. 1, in order to reduce the power consumption, the SRAM is connected to the output of the PROM, and the logical value of the PROM storage node is transferred to the SRAM by controlling the gate terminal of P2 by the RST terminal, so that there is an effect of preventing constant flow of the current I.

### Second Embodiment

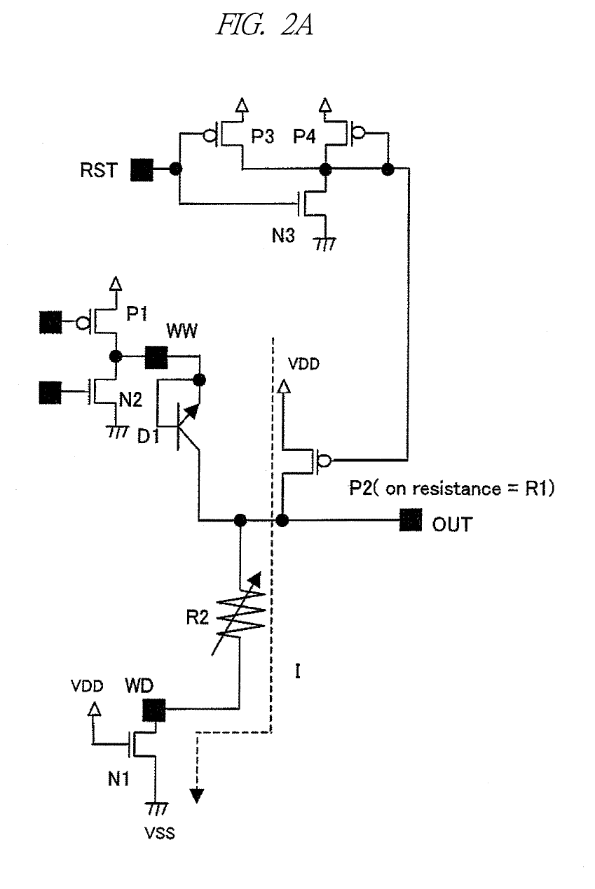

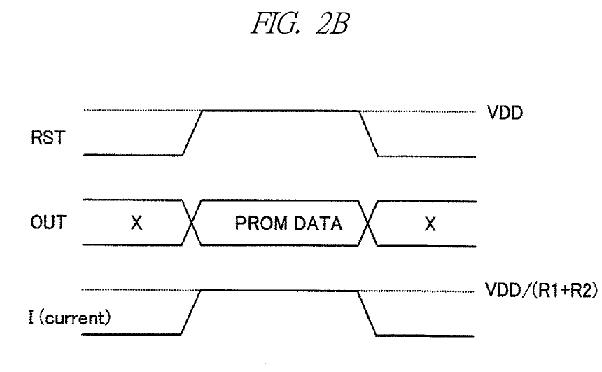

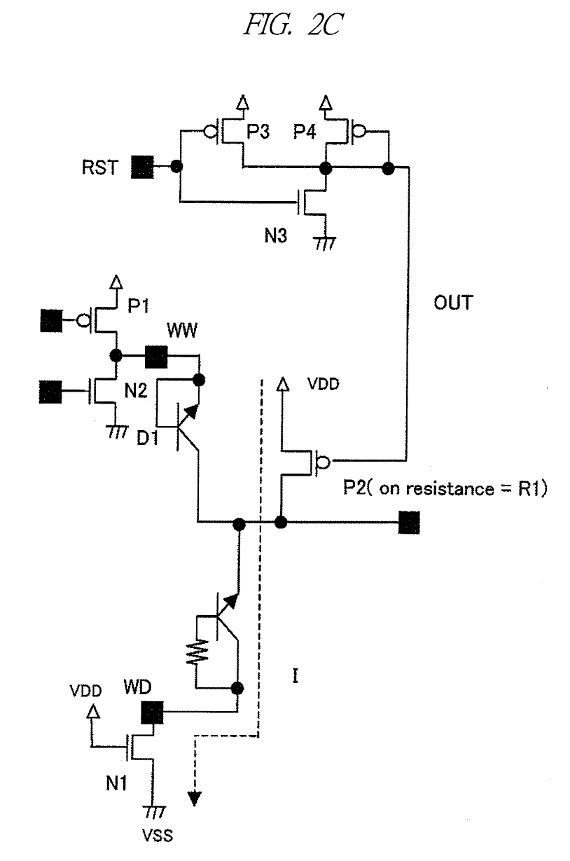

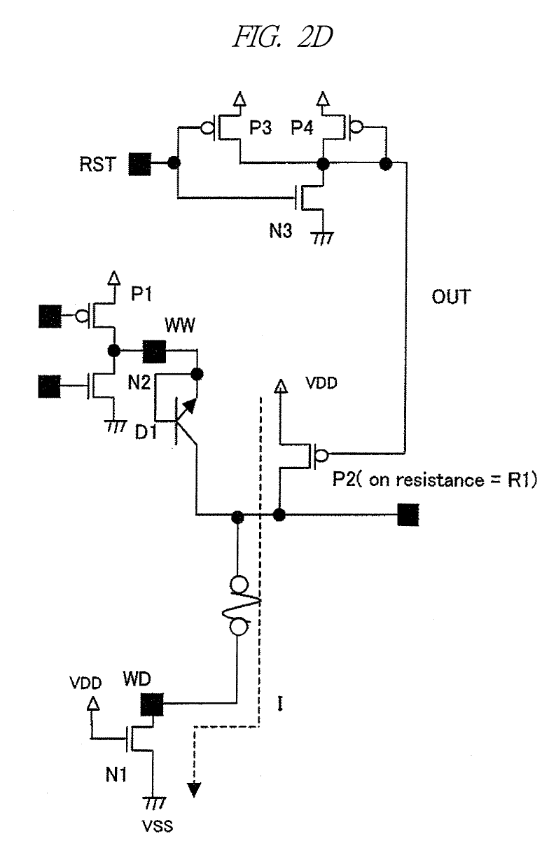

FIGS. 2A to 2D are diagrams for describing a part corresponding to a resistance-division-type PROM (programmable read only memory) configuring the semiconductor storage device of FIG. 1. Some embodiments of the resistance-division-type PROM will be described with reference to FIGS. 2A to 2D. As illustrated in FIG. 2A, a resistance-change storage element is configured with: a resistor R1; a resistor R2 whose resistance value is variable; a word-line driver P1 to be turned ON upon changing the resistance value; a data-line driver N1 to be turned ON upon normal operation and changing the resistance value; a word-line driver P2 to be turned ON upon outputting storage information of the PROM; and a transistor transferring a reset signal (RST).

In FIG. 2A, a symbol R2 denotes a resistor element whose resistance value is variable. A symbol D1 connected to R2 in series denotes a diode-connected bipolar transistor, and it carries current in a forward direction upon changing the resistance value of R2. A PMOS transistor denoted by a symbol P1 and an NMOS transistor denoted by a symbol N2 are connected to D1 in series, and an NMOS transistor denoted by a symbol N1 is connected to R2 in series. Upon changing the resistance value, a gate voltage of N1 is set to VDD and a gate voltage of P1 is set to VSS to carry current from a power supply terminal VDD of P1 to a power supply terminal VSS of N1 via D1 and R2. Gate terminals of a PMOS transistor denoted by a symbol P3 and an NMOS transistor denoted by a symbol N3 are controlled by a reset signal RST, and a gate terminal and a drain terminal of a PMOS transistor denoted by a symbol P4 are connected to both of N3 and P3. N3 and P4 are turned ON when the reset signal RST is set to VDD, so that voltage of a node PUP connected to a gate terminal of a PMOS transistor denoted by a symbol P2 is dropped. Accordingly, the PMOS P2 is turned ON. When a value of ON resistance at this time is assumed to R1, voltage of a PROM storage node (PROM node) becomes a value of “VDD-R1×VDD/(R1+R2)”, so that information of 1 or 0 is outputted. FIG. 2B illustrates a timing chart at this time. In the resistance-division-type PROM illustrated in FIG. 2A, when the RST signal is at VDD, a logical value of output “OUT” is determined, and current “I” of “VDD/(R1+R2)” flows at the same time.

In both of a fuse element using meltdown of a metal wire and an antifuse element of a bipolar transistor used as a variable resistor in the resistance-division-type PROM described above, once their resistance values are changed, it is impossible to recover the values to their original resistance values. Therefore, according to the present embodiment of FIG. 2A, from the above-described characteristics, the logical value of 0 or 1 in each memory cell in the PROM can be changed only once, and the logical value of 0 or 1 can be outputted any number of times as long as inputting the RST signal.

In the resistance-division-type PROM illustrated in FIGS. 2A to 2D, the logical value of 1 or 0 is outputted with dividing power supply voltage by R1 and R2. When information of “1” is stored in the PROM, the resistance value R2 is set to be higher than the resistance value R1, and when information of “0” is stored in the PROM, the resistance value R2 is set to be lower than R1.

For the resistor R2, an antifuse element whose resistance value is decreased by breaking a junction between an emitter and a base of a bipolar transistor to short out between the emitter and a collector or a fuse element whose resistance value is increased by meltdown of a metal wire by carrying current in the metal wire is used. FIG. 2C illustrates a whole configuration of a semiconductor storage device when the antifuse element is used as a variable resistor of a resistance-division-type PROM, and FIG. 2D illustrates a whole configuration of a semiconductor storage device when the fuse element is used as the variable resistor of the resistance-division-type PROM.

In the resistance-division-type PROM using the antifuse element illustrated in FIG. 2C, the resistance value R2 before varying its value is high, and the output logical value before varying it is 1. Therefore, in a semiconductor storage device in which “1” is stored so often in a whole memory, the number of variable resistors can be reduced.

In the resistance-division-type PROM using the fuse element illustrated in FIG. 2D, the resistance value R2 before varying its value is low, and the output logical value before varying it is 0. Therefore, in a semiconductor storage device in which “0” is stored so often in a whole memory, the number of variable resistors can be reduced.

Upon outputting storage information of the PROM, the RST signal is set to High as illustrated in the timing chart of FIG. 2B to carry the current I from the power supply voltage via R1, P2, R2 and N1, so that the voltage of “VDD−R1×VDD/(R1+R2)” is generated in the output terminal OUT to output the information of 1 or 0.

In the resistance-division-type PROM described above, stationary current of I×(number of bits) flows, and “I” increases when the number of bits for storing “0” increases. Therefore, the SRAM of a nonvolatile memory is connected to the resistance-division-type PROM for each 1 bit as illustrated in FIG. 1.

<“0”Writing Operation>

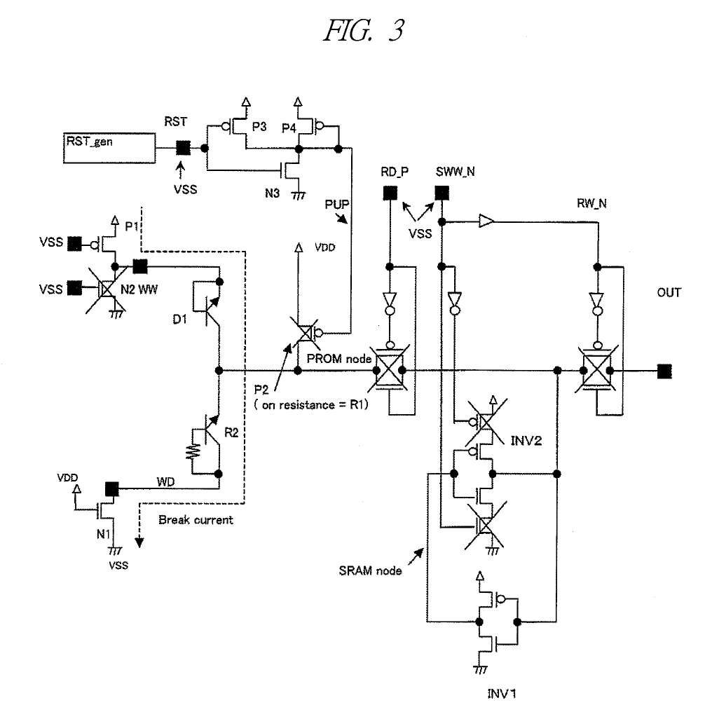

FIG. 3 is a diagram illustrating an operation of the semiconductor storage device when “0” is written in another embodiment of using the antifuse element of the bipolar transistor as the variable resistor of the resistance-division-type PROM configuring the semiconductor storage device of FIG. 1. When “0” is stored in the resistance-division-type PROM using an antifuse bipolar transistor element for R2 illustrated in FIG. 1, as illustrated in FIG. 3, both of a word-line driver P1 and a data-line driver N1 are turned ON to carry “Break current” to the bipolar transistor R2 whose resistance value is varied, so that the junction between the emitter and the base of R2 is broken to short out between the emitter and the collector of R2. Accordingly, the resistance value of R2 is decreased, so that “0” can be stored.

<SRAM Writing Operation>

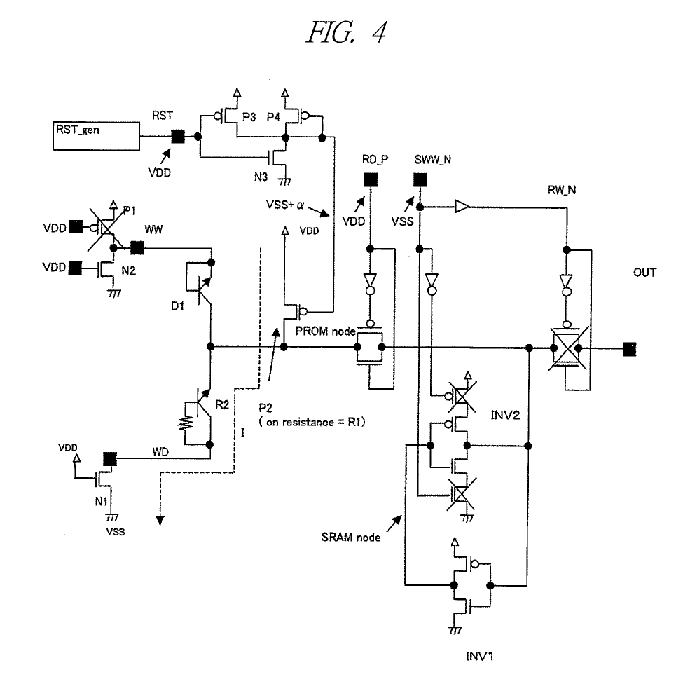

FIG. 4 is a diagram illustrating an operation of the semiconductor storage device when storage information of the resistance-division-type PROM written by the operation of FIG. 3 is written to the SRAM. For storing the storage information of the resistance-division-type PROM into the SRAM, as illustrated in FIG. 4, by setting the reset signal (RST) to VDD, RW_N signal to VSS, SWW_N signal to VSS and RD_P signal to VDD, current “I” flows in P2, R2 and N1 in the PROM, and the PROM storage node has potential corresponding to 1 or 0 by the resistance division of the ON resistor R1 of P2 and the variable resistor R2. When the RD_P signal is set to High in this state, the potential corresponding to 1 or 0 of the PROM storage node is propagated to an SRAM storage node via a pass transistor and an inverter. In this manner, an inversion logical value of the PROM storage node is written in the SRAM storage node.

<SRAM Storage Information Outputting Operation>

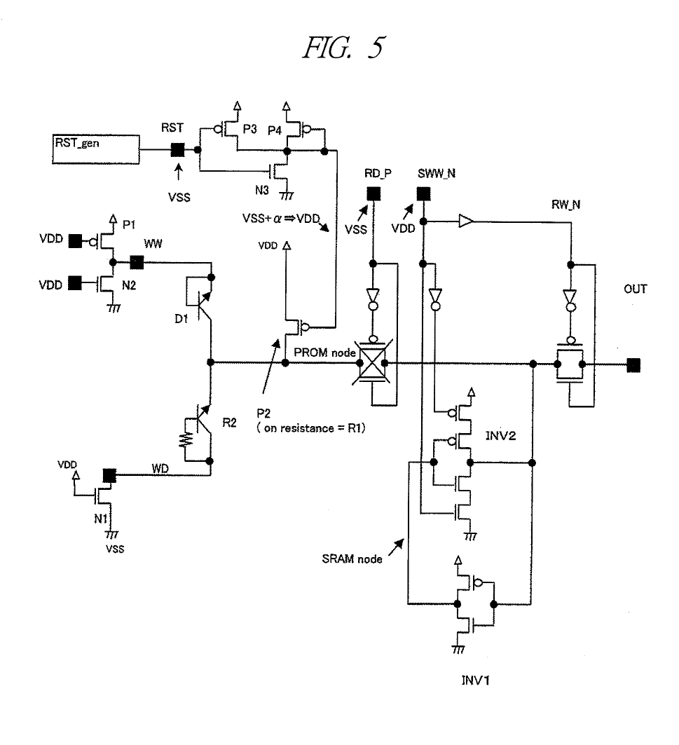

FIG. 5 is a diagram illustrating an operation of the semiconductor storage device when the storage information of the SRAM written by the operation of FIG. 4 is outputted. After finishing the writing operation, the RD_P signal is set to Low to turn OFF the pass transistor on the former stage, so that connection between the PROM storage node and the SRAM storage node is cut off. Next, the RST signal is set to Low to eliminate the stationary current I, the SWW_N signal is set to High, and an inverter (INV2) and a pass transistor on a latter stage in the SRAM are sequentially turned ON, so that the inversion logical value of the SRAM storage node, that is, the logical value of the PROM storage node is outputted to an OUT terminal.

### Third Embodiment

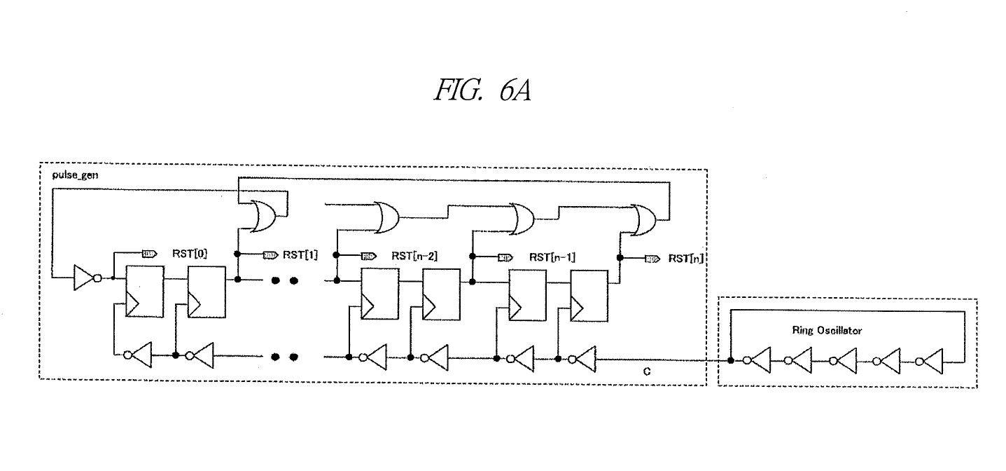

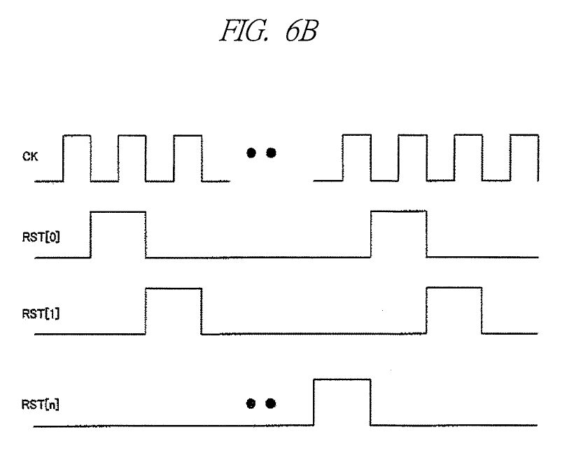

FIG. 6A is a diagram illustrating still another embodiment of a circuit configuration of the reset signal generating logic circuit configuring the semiconductor storage device of FIG. 1. FIG. 6A illustrates the reset signal generating logic circuit (RST_gen) inputting signals to the resistance-division-type PROM. The reset signal generating logic circuit is configured with, for example, a ring oscillator in which inverters are connected in multiple stages and a pulse generating logic circuit (pulse_gen) configured with scan resistors.

FIG. 6B is a diagram illustrating a timing chart of each signal waveform in the reset signal generating logic circuit of FIG. 6A. As illustrated in the timing chart of FIG. 6B, when continuous pulse signal CK generated by the ring oscillator is inputted to the pulse generating logic circuit, pulses are sequentially generated in output terminals RST[0] to RST[n].

The reset signal generating logic circuit does not need control signals from outside, and it continues to sequentially generate the RST signals as long as power supply is applied.

### Fourth Embodiment

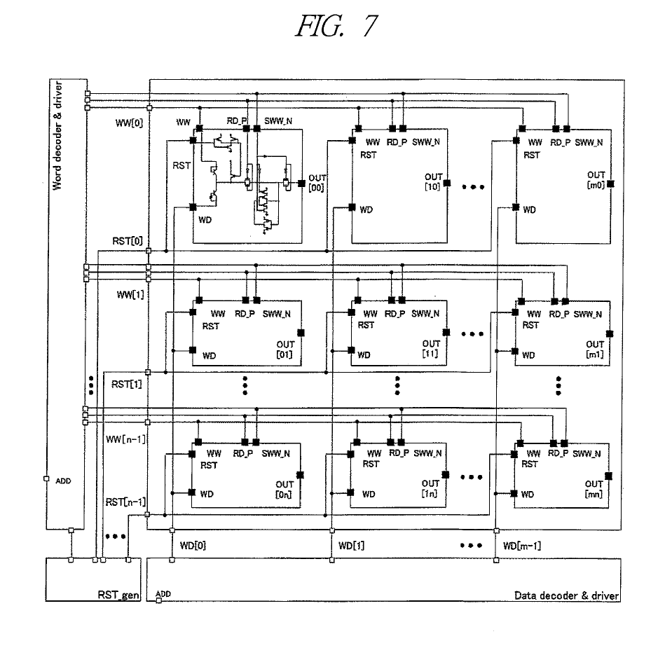

FIG. 7 is a diagram illustrating still another embodiment of a memory array configuration of n×m bits (n and m are integer numbers of 2 or larger which are independent of each other, and n represents the total number of rows and m represents the total number of columns, respectively. Hereinafter, the same goes for n and m below.) in which a semiconductor storage device of the present invention including a resistance-division-type PROM, an SRAM and a reset terminal is applied as each memory cell, and a word-line decoder/driver logic circuit, a data-line decoder/driver logic circuit and a reset signal generating logic circuit are combined to the memory cells. In this memory array configuration, a plurality of memory cells are related to each other by rows whose total number is n and columns whose total number is m.

In FIG. 7, word-line terminals (WW) and SRAM pass transistor input terminals (RD_P and SWW_N) in each of the memory cells in each row are respectively connected to the word-line decoder/driver logic circuit (word decoder & driver) through common lines, and data-line terminals (WD) in each of the memory cells in each column are respectively connected to the data-line decoder/driver logic circuit (data decoder & driver) through common lines. More specifically, the word-line terminals (WW) in each row are connected to the word-line decoder/driver logic circuit via a common word-line terminal (WW[j]) (j=0, 1, 2, . . . , n−1) for each row, and the data-line terminals (WD) in each column are connected to the data-line decoder/driver logic circuit via a common data-line terminal (WD[k]) (k=0, 1, 2, . . . , m−1) for each column. Here, “j” represents a row number and “k” represents a column number, respectively. Also, reset terminals (RST) in each of the memory cells in each row are connected to the reset signal generating logic circuit (RST_gen) via a common reset terminal (RST[j]) (j=0, 1, 2, n−1) through a common line for each row. The word-line decoder/driver logic circuit is connected to the RST_gen, and it receives the reset signal (RST signal) generated from the RST_gen to generate signals (RD_P signal and SWW_N signal) to be transmitted to each terminal of the RD_P and SWW_N for each row.

When the logical value of “0” is written to the PROM of each memory cell, an address signal is inputted to the word-line decoder/driver logic circuit and the data-line decoder/driver logic circuit in a state of stopping the output of the RST_gen to select 1 bit from the memory cells of n×m bits, and current for breaking the antifuse is supplied from the word-line terminal WW to the data-line terminal WD in the memory cell of the selected 1 bit, so that the antifuse is broken. By this means, a resistance value of the antifuse element is decreased, and the value of the PROM storage node can be set to “0” upon inputting the RST signal. The above-described “0” writing operation is repeatedly performed to all of memory cells to which “0” is to be stored.

In order to output the logical value of 0 or 1 written in the PROM to the OUT terminal, the RST signal is outputted from the RST_gen, and the RD_P signal and the SWW_N signal are generated from the word-line decoder/driver logic circuit for each row, so that writing to the SRAM of the PROM storage node and outputting to the OUT terminal of the SRAM storage node are repeatedly performed for each row.

In FIG. 7, the RST signal, the RD_P signal and the SWW_N signal are commonly connected for each of the word lines, respectively, and n lines of the RST signal line are connected to the reset signal generating logic circuit in the whole memory array. In this configuration, the reset operation is performed in each 1 word line (each of m bits), and therefore, stationary current volume is expressed by I×m.

According to the present embodiment, it is possible to achieve such a PROM that, even if an output value of the SRAM is abnormally operated due to temporary blackout, the output value is automatically recovered to a correct value by reset signals sequentially issued from the RST_gen for each word line without input signals from outside, with the reset signal lines of at most n order and the power consumption of about I×m or lower. Therefore, there is an effect that the present invention contributes to the circuit area reduction in addition to the reduction in power consumption.

### Fifth Embodiment

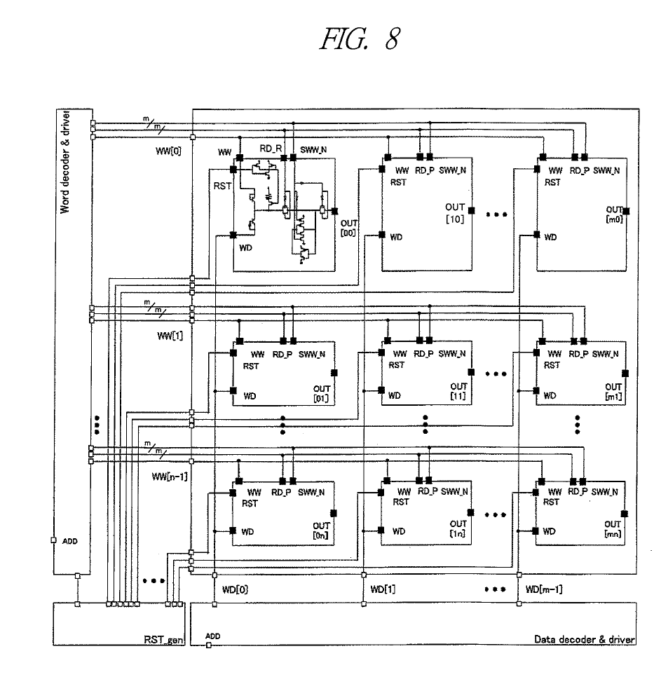

FIG. 8 is a diagram illustrating still another embodiment of a memory array configuration of n×m bits in which a semiconductor storage device of the present invention including a resistance-division-type PROM, an SRAM and a reset terminal is applied as each memory cell, and a word-line decoder/driver logic circuit, a data-line decoder/driver logic circuit and a reset signal generating logic circuit are combined to the memory cells. In this memory array configuration, a plurality of memory cells are related to each other by rows whose total number is n and columns whose total number is m.

In FIG. 8, word-line terminals (WW) in each of the memory cells in each row are connected to the word-line decoder/driver logic circuit (word decoder & driver) via a common word-line terminal (WW[j]) (j=0, 1, 2, . . . , n−1) through a common line for each row. Here, “j” represents a row number. Meanwhile, both of SRAM pass transistor input terminals (RD_P and SWW_N) in each bit are respectively connected to the word-line decoder/driver logic circuit. More specifically, in each row, m pieces of RD_P terminals and m pieces of SWW_N terminals corresponding to m pieces of memory cells are connected to the word-line decoder/driver logic circuit through respectively individual m lines of control lines. Data-line terminals (WD) in each column are connected to the data-line decoder/driver logic circuit (data decoder & driver) via a common data-line terminal (WD [k]) (k=0, 1, 2, . . . , m−1) for each column. Here, “k” represents a column number. Also, a reset terminal (RST) in each memory cell is connected to the reset signal generating logic circuit “RST_gen” for each bit. More specifically, in each row, m pieces of RST terminals corresponding to m pieces of memory cells are connected to the RST_gen through respectively individual m lines of control lines. The word-line decoder/driver logic circuit is connected to the RST_gen, and it receives the reset signal (RST signal) generated from the RST_gen to generate signals (RD_P signal and SWW_N signal) to be transmitted to the RD_P terminal and SWW_N terminal in each memory cell.

When the logical value of “0” is written to the PROM of each memory cell, an address signal is inputted to the word-line decoder/driver logic circuit and the data-line decoder/driver logic circuit in a state of stopping the output of the RST_gen to select 1 bit from the memory cells of n×m bits, and current for breaking the antifuse is supplied from the word-line terminal WW to the data-line terminal WD in the memory cell of the selected 1 bit, so that the antifuse is broken. By this means, a resistance value of the antifuse element is decreased, and the value of the PROM storage node can be set to “0” upon inputting the RST signal. The above-described “0” writing operation is repeatedly performed to all of memory cells to which “0” is to be stored.

In order to output the logical value of 0 or 1 written in the PROM to the OUT terminal, the RST signal is outputted from the RST_gen, and the RD_P signal and the SWW_N signal are generated from the word-line decoder/driver logic circuit for each bit, so that writing to the SRAM of the PROM storage node and outputting to the OUT terminal of the SRAM storage node are repeatedly performed.

In FIG. 8, the RST signal, the RD_P signal and the SWW_N signal are respectively generated for each bit, and n×m lines of the RST signal lines are connected to the reset signal generating logic circuit in the whole memory array. Therefore, according to the configuration of the present embodiment of FIG. 8, the reset operation is performed for each 1 bit, and stationary current volume is expressed by I. As a result, consumption current (power consumption) can be lowered compared with the above-described configuration. Also, since the number of RST signal lines is increased and all or a part of m pieces of memory cells in each row can be independently controlled, the number of bits which are simultaneously subjected to a reset operation can be reduced, and as a result, consumption current (power consumption) can be lowered.

In order to shorten the time for the recovery when the abnormal operation of the SRAM is caused, frequencies of the continuous pulses generated in the ring oscillator are increased or the number of the RST signal lines is reduced to increase the number of bits which are simultaneously subjected to a reset operation. In this manner, the abnormal operation can be recovered to a normal operation in shorter time. The number of divisions for the RST signal can be arbitrarily set with taking the required power consumption and time for the recovery into consideration.

According to the present embodiment, it is possible to achieve such a PROM that, even if an output value of the SRAM is abnormally operated due to temporary blackout, the output value is automatically recovered to a correct value by reset signals sequentially issued from the RST_gen for each 1 bit without input signals from outside, with the power consumption of I or lower.

### Sixth Embodiment

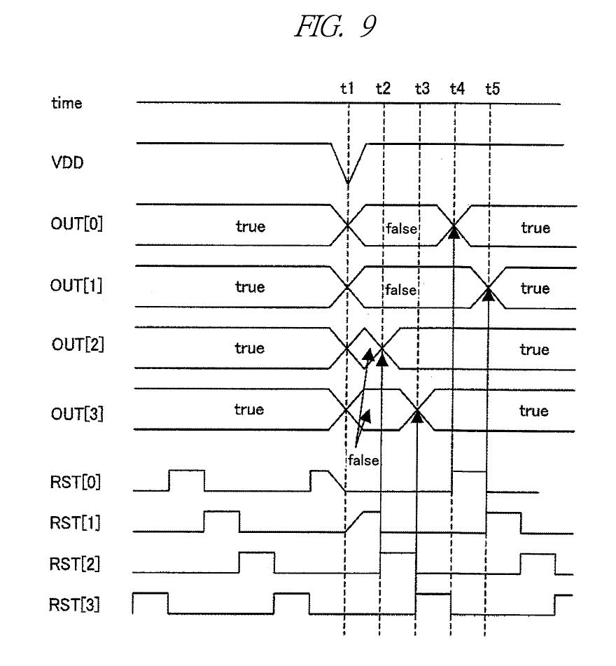

FIG. 9 illustrates an example of a timing chart in a configuration in which reset signals are inputted to a 4-bit memory array and a reset signal generating logic circuit for each bit as still another embodiment illustrating a recovery operation process from the abnormal operation state of the SRAM due to temporary blackout and others to the normal state. In FIG. 9, “abnormal operation (false)” is caused to the output of each bit due to the rapid drop of power supply voltage (VDD) caused at time t1, and then, outputs of out[2], out[3], out[0] and out[1] are recovered to “normal operation (true)” by reset signals issued sequentially at the times t2, t3, t4 and t5, respectively.

According to the present embodiment, even if the storage information of the SRAM is abnormally operated due to the rapid drop of power supply voltage, α-ray or others, the abnormal operation can be recovered to a normal operation by reset signals issued sequentially without input signals from outside.

In the foregoing, in the configurations having a nonvolatile memory and a volatile memory according to the above-described embodiments of the present invention, the abnormal operation caused by the change in storage information of the nonvolatile memory due to temporary blackout, α-ray or others can be prevented, and even if the abnormal operation is caused, the abnormal operation can be recovered to a normal operation regardless of the presence of the detection of the abnormal operation, and the correctness of the storage data of the nonvolatile memory can be achieved with the low power consumption equivalent to that of the conventional arts.

What is claimed is:

1. A semiconductor storage device comprising:
a nonvolatile memory;
a volatile memory whose input is connected to an output of the nonvolatile memory; and
a reset terminal connected to an input of the nonvolatile memory, wherein
the semiconductor storage device has a function of periodically transferring data from the nonvolatile memory to the volatile memory in accordance with a logical value of a reset signal inputted from the reset terminal.

2. The semiconductor storage device according to claim 1, wherein
the nonvolatile memory includes a resistance-division-type PROM whose resistance value is changed to store information of 0 or 1.

3. The semiconductor storage device according to claim 2, wherein
the resistance-division-type PROM includes an antifuse element in which a junction between an emitter and a base of a bipolar transistor is broken to short out between the emitter and a collector, thereby reducing the resistance value.

4. The semiconductor storage device according to claim 2, wherein
the resistance-division-type PROM includes a fuse element in which a metal wire is melted down by supplying current to the metal wire, thereby increasing the resistance value.

5. The semiconductor storage device according to claim 1, wherein
the volatile memory includes an SRAM to which information stored in the nonvolatile memory is transferred in accordance with the reset signal and which retains the information and outputs the stored information.

6. The semiconductor storage device according to claim 1, wherein
the reset signal is collectively transmitted at any one of transfer rates of each 1 bit, each 1 word and each predetermined arbitrary bit from a pulse generator, and the reset signal is periodically inputted from the reset terminal with taking the transfer rate as one unit.

7. The semiconductor storage device according to claim 6, wherein
the pulse generator is an embedded pulse generator integrated on the same semiconductor substrate with at least one circuit configuring the semiconductor storage device.

8. The semiconductor storage device according to claim 6, wherein
the pulse generator is an external pulse generator connected from outside to a semiconductor substrate on which at least one circuit configuring the semiconductor storage device is formed.

9. The semiconductor storage device according to claim 1, wherein
the nonvolatile memory, the volatile memory and the reset terminal are integrated on the same semiconductor substrate with other circuits using the nonvolatile memory, the volatile memory and the reset terminal.

10. A semiconductor storage device having a memory cell array configuration comprising:
a plurality of memory cells related to each other by rows whose total number is n and columns whose total number is m, respectively, when n and m are integer numbers of 2 or larger which are independent of each other;
a word-line decoder/driver circuit to which a word-line terminal and an input terminal of an SRAM pass transistor in each of the plurality of memory cells are connected through common lines for each row;
a data-line decoder/driver circuit to which a data-line terminal in each of the plurality of memory cells is connected through common lines for each column; and
a reset signal generating unit to which a reset terminal in each of the plurality of memory cells is connected through common lines for each row and which is connected to the word-line decoder/driver circuit, wherein
each of the plurality of memory cells includes a nonvolatile memory, a volatile memory whose input is connected to an output of the nonvolatile memory and a reset terminal connected to an input of the nonvolatile memory and to the reset signal generating unit, and
the semiconductor storage device has a function of periodically transferring data from the nonvolatile memory to the volatile memory in accordance with a logical value of a reset signal inputted from the reset terminal.

11. The semiconductor storage device according to claim 10, wherein
the nonvolatile memory includes a resistance-division-type PROM whose resistance value is changed to store information of 0 or 1.

12. The semiconductor storage device according to claim 11, wherein
the resistance-division-type PROM includes an antifuse element in which a junction between an emitter and a base of a bipolar transistor is broken to short out between the emitter and a collector, thereby reducing the resistance value.

13. The semiconductor storage device according to claim 11, wherein
the resistance-division-type PROM includes a fuse element in which a metal wire is melted down by supplying current to the metal wire, thereby increasing the resistance value.

14. The semiconductor storage device according to claim 10, wherein
the volatile memory includes an SRAM to which information stored in the nonvolatile memory is transferred in accordance with the reset signal and which retains the information and outputs the stored information.

15. A semiconductor storage device having a memory cell array configuration comprising:
a plurality of memory cells related to each other by rows whose total number is n and columns whose total number is m, respectively, when n and m are integer numbers of 2 or larger which are independent of each other;
a word-line decoder/driver circuit to which a word-line terminal in each of the plurality of memory cells is connected through common lines for each row and to which an input terminal of an SRAM pass transistor in each of the plurality of memory cells is individually connected for each bit;
a data-line decoder/driver circuit to which a data-line terminal in each of the plurality of memory cells is connected through common lines for each column; and
a reset signal generating unit to which a reset terminal in each of the plurality of memory cells is individually connected for each bit and which is connected to the word-line decoder/driver circuit, wherein
each of the plurality of memory cells includes a nonvolatile memory, a volatile memory whose input is connected to an output of the nonvolatile memory and a reset terminal connected to an input of the nonvolatile memory and to the reset signal generating unit, and
the semiconductor storage device has a function of periodically transferring data from the nonvolatile memory to the volatile memory in accordance with a logical value of a reset signal inputted from the reset terminal.

16. The semiconductor storage device according to claim 15, wherein
the nonvolatile memory includes a resistance-division-type PROM whose resistance value is changed to store information of 0 or 1.

17. The semiconductor storage device according to claim 16, wherein
the resistance-division-type PROM includes an antifuse element in which a junction between an emitter and a base of a bipolar transistor is broken to short out between the emitter and a collector, thereby reducing the resistance value.

18. The semiconductor storage device according to claim 16, wherein
the resistance-division-type PROM includes a fuse element in which a metal wire is melted down by supplying current to the metal wire, thereby increasing the resistance value.

19. The semiconductor storage device according to claim 15, wherein
the volatile memory includes an SRAM to which information stored in the nonvolatile memory is transferred in accordance with the reset signal and which retains the information and outputs the stored information.
